(19) United States
(12) Patent Application Publication
(10) Pub. No.: US 2018/0012957 A1
(43) Pub. Date: Jan. 11, 2018

(54) SILICON CARBIDE SEMICONDUCTOR DEVICE

(71) Applicant: Sumitomo Electric Industries, Ltd., Osaka-shi (JP)

(72) Inventor: Toru Hiyoshi, Osaka-shi (JP)

(21) Appl. No.: 15/548,699

(22) PCT Filed: Feb. 8, 2016
(86) PCT No.: PCT/JP2016/053641

§ 371 Date: Aug. 3, 2017

(30) Foreign Application Priority Data
Mar. 24, 2015 (JP) 2015-060680

(51) Int. Cl. H01L 29/06; H01L 29/36; H01L 21/78; H01L 29/16; H01L 29/78; H01L 29/66

(52) U.S. Cl. CPC H01L 29/0615; H01L 29/7801; H01L 29/66068; H01L 21/78; H01L 29/1608; H01L 29/0619; H01L 29/36

(57) ABSTRACT

A silicon carbide semiconductor device has a silicon carbide substrate and an insulating film. The silicon carbide substrate includes a termination region having a peripheral edge, and an element region surrounded by the termination region. The insulating film is provided on the termination region. The termination region includes a first impurity region having a first conductivity type, and a field stop region having the first conductivity type, being in contact with the first impurity region and having a higher impurity concentration than the first impurity region. The field stop region is at least partially exposed at the peripheral edge.

### TECHNICAL FIELD

The present invention relates to silicon carbide semiconductor devices.

### BACKGROUND ART

In recent years, silicon carbide has been increasingly employed as a material forming a semiconductor device in order to allow for a higher breakdown voltage, lower loss, the use in a high-temperature environment and the like of the semiconductor device. For example, Naoki Kaji and three others, “Ultrahigh-Voltage SiC PiN Diodes with an Improved Junction Termination Extension Structure and Enhanced Carrier Lifetime,” Japanese Journal of Applied Physics, 52, 2013, 070204 (NPD 1) discloses a silicon carbide PiN (P intrinsic N) diode including an epitaxial layer having a film thickness of 186 μm and capable of achieving a breakdown voltage of 18.9 kV.

### CITATION LIST

### Non Patent Document

NPD 1: Naoki Kaji and three others, “Ultrahigh-Voltage SiC PiN Diodes with an Improved Junction Termination Extension Structure and Enhanced Carrier Lifetime,” Japanese Journal of Applied Physics, 52, 2013, 070204

### SUMMARY OF INVENTION

### Technical Problem

A silicon carbide semiconductor device often employs a structure similar to a termination region used in a silicon semiconductor device. However, when a structure similar to a termination region used in a silicon semiconductor device is employed in a silicon carbide semiconductor device, it has been difficult to realize a silicon carbide semiconductor device having a sufficiently high breakdown voltage.

An object of one embodiment of the present invention is to provide a silicon carbide semiconductor device capable of achieving an improved breakdown voltage.

### Solution to Problem

A silicon carbide semiconductor device according to one embodiment of the present invention has a silicon carbide substrate and an insulating film. The silicon carbide substrate includes a termination region having a peripheral edge, and an element region surrounded by the termination region. The insulating film is provided on the termination region. The termination region includes a first impurity region having a first conductivity type, and a field stop region having the first conductivity type, being in contact with the first impurity region and having a higher impurity concentration than the first impurity region. The field stop region is at least partially exposed at the peripheral edge.

### Advantageous Effects of Invention

According to one embodiment of the present invention, a silicon carbide semiconductor device capable of achieving an improved breakdown voltage can be provided.

### BRIEF DESCRIPTION OF DRAWINGS

FIG. 1 is a schematic vertical sectional view showing the structure of a silicon carbide semiconductor device according to an embodiment of the present invention, and corresponds to a schematic sectional view taken along the line I-I in a direction of arrows in FIG. 3.

FIG. 2 is a schematic plan view showing the structure of a silicon carbide substrate of the silicon carbide semiconductor device according to the embodiment of the present invention.

FIG. 3 is a schematic transverse sectional view showing the structure of the silicon carbide substrate of the silicon carbide semiconductor device according to the embodiment of the present invention.

FIG. 4 is a schematic transverse sectional view showing the structure of a variation of the silicon carbide substrate of the silicon carbide semiconductor device according to the embodiment of the present invention.

FIG. 5 is a schematic vertical sectional view showing a first step of a method of manufacturing the silicon carbide semiconductor device according to the embodiment of the present invention.

FIG. 6 is a schematic plan view showing the first step of the method of manufacturing the silicon carbide semiconductor device according to the embodiment of the present invention.

FIG. 7 is a schematic vertical sectional view showing a second step of the method of manufacturing the silicon carbide semiconductor device according to the embodiment of the present invention.

FIG. 8 is a schematic transverse sectional view showing the second step of the method of manufacturing the silicon carbide semiconductor device according to the embodiment of the present invention.

FIG. 9 is a schematic vertical sectional view showing a third step of the method of manufacturing the silicon carbide semiconductor device according to the embodiment of the present invention.

FIG. 10 is a schematic vertical sectional view showing a fourth step of the method of manufacturing the silicon carbide semiconductor device according to the embodiment of the present invention.

FIG. 11 is a schematic vertical sectional view showing a variation of the second step of the method of manufacturing the silicon carbide semiconductor device according to the embodiment of the present invention.

FIG. 12 is a schematic vertical sectional view showing the structure of a MOSFET (Metal Oxide Semiconductor Field Effect Transistor) according to an example.

FIG. 13 is a diagram showing distribution of electron concentration in the MOSFET of the example, when a voltage of 5 V is applied between the drain electrode and the source electrode, and the voltage of each of the source electrode and the gate electrode is set to 0 V.

FIG. 14 is a diagram showing distribution of electron concentration in the MOSFET of the example, when a voltage of 6500 V is applied between the drain electrode and the source electrode, and the voltage of each of the source electrode and the gate electrode is set to 0 V.

FIG. 15 is a schematic vertical sectional view showing the structure of a MOSFET according to a comparative example.

FIG. 16 is a diagram showing distribution of electron concentration in the MOSFET of the comparative example, when a voltage of 5 V is applied between the drain electrode and the source electrode, and the voltage of each of the source electrode and the gate electrode is set to 0 V.

FIG. 17 is a diagram showing distribution of electron concentration in the MOSFET of the comparative example, when a voltage of 6500 V is applied between the drain electrode and the source electrode, and the voltage of each of the source electrode and the gate electrode is set to 0 V.

### DESCRIPTION OF EMBODIMENTS

### Description of Embodiment of the Present Invention

In a silicon carbide semiconductor device having a silicon carbide substrate and an insulating film provided on the silicon carbide substrate, a high-density interface state exists at an interface between the silicon carbide substrate and the insulating layer. When electrons are trapped in the interface state, fixed charges are generated at the interface between the silicon carbide substrate and the insulating film. Electrons present in an n type region (drift region) which is part of the silicon carbide substrate and the electrons trapped in the interface state repel each other, causing a depletion layer to extend toward the n type region. Since an electric field (voltage) is applied to the depletion layer, when the depletion layer extends toward a termination region, a high voltage is applied to the termination region. In particular, when the depletion layer extends in a peripheral edge direction of a chip past a field stop region, a high voltage is applied to the peripheral edge. When a high voltage is applied to the peripheral edge, a leak current is generated at the peripheral edge, for example, which may result in degradation in breakdown voltage of the silicon carbide semiconductor device.

In order to improve the breakdown voltage of a silicon carbide semiconductor device, a drift region having a low impurity concentration is required. With a low impurity concentration in the drift region, a depletion layer tends to extend toward the drift region when a reverse bias is applied to a pn junction. Accordingly, the structure of a termination region in which the extension of a depletion layer to the termination region is suppressed is obtained, particularly in a silicon carbide semiconductor device having a high breakdown voltage. In addition, the density of an interface state in a silicon carbide semiconductor device is higher than the density of an interface state in a silicon semiconductor device by an order of magnitude or more. Thus, a depletion layer is more likely to extend in a silicon carbide semiconductor device than in a silicon semiconductor device. Accordingly, it is required to suppress the extension of a depletion layer to a termination region more in a silicon carbide semiconductor device than in a silicon semiconductor device.

The inventor performed simulations of distribution of electron concentration, in order to study the effect of fixed charges in an interface state on a depletion layer.

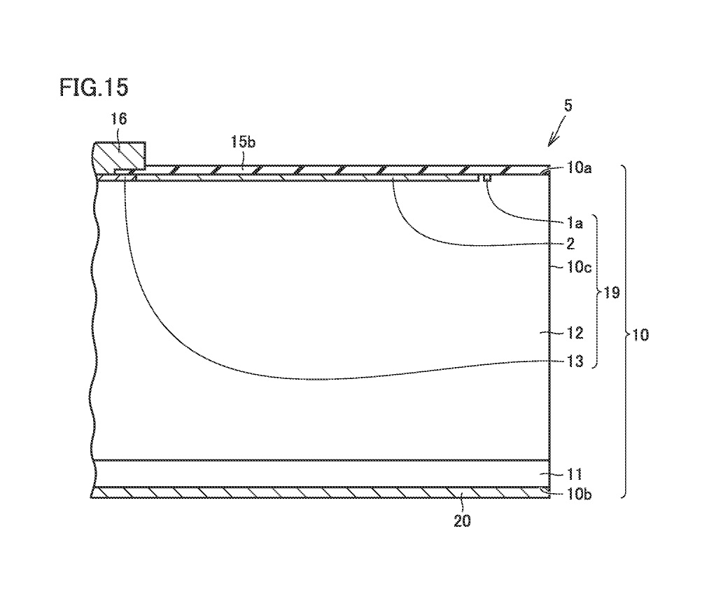

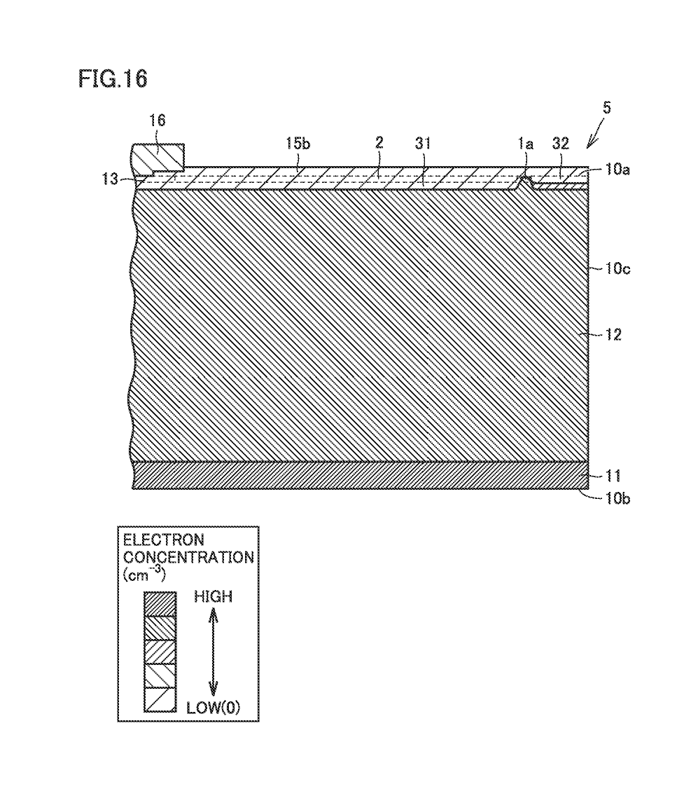

FIG. 15 is a schematic sectional view showing the structure of a MOSFET 5 according to a comparative example. MOSFET 5 mainly includes a silicon carbide substrate 10, a source electrode 16, a drain electrode 20, a gate electrode (not shown), and an insulating film 15b. Silicon carbide substrate 10 is formed of a silicon carbide single-crystal substrate 11 and a silicon carbide epitaxial layer 19. Silicon carbide epitaxial layer 19 includes a JTE (Junction Termination Extension) region 2, a field stop region 1a, a body region 13, and a source region (not shown). Insulating film 15b is provided on JTE region 2 and field stop region 1a. Source electrode 16 is provided on a first main surface 10a of silicon carbide substrate 10, and drain electrode 20 is provided on a second main surface 10b. Source electrode 16 is in contact with a source region provided in body region 13. Field stop region 1a is provided between JTE region 2 and a peripheral edge 10c.

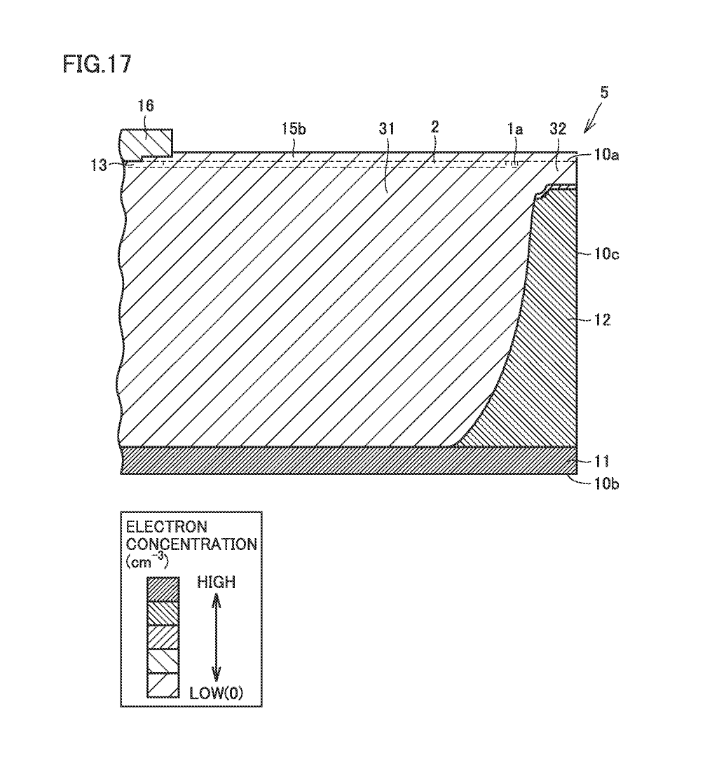

FIG. 16 is a diagram showing distribution of electron concentration in MOSFET 5 of the comparative example, when a voltage of 5 V is applied between drain electrode 20 and source electrode 16, and the voltage of each of source electrode 16 and the gate electrode is set to 0 V. Negative fixed charges of Q_{eff}=1×10¹² cm⁻² were introduced into an interface between silicon carbide substrate 10 and insulating film 15b. As shown in FIG. 16, a depletion layer 31 protrudes from JTE region 2 into a drift region 12. A depletion layer 32 protrudes from insulating film 15b into drift region 12 between field stop region 1a and peripheral edge 10c as well. It is noted that a depletion layer is a region having an electron concentration of substantially zero in silicon carbide substrate 10. Since there are substantially no electrons in insulating film 15b and JTE region 2, this region also has an electron concentration of substantially zero.

FIG. 17 is a diagram showing distribution of electron concentration in MOSFET 5 of the comparative example, when a voltage of 6500 V is applied between drain electrode 20 and source electrode 16, and the voltage of each of source electrode 16 and the gate electrode is set to 0 V. As shown in FIG. 17, when a high voltage is applied between drain electrode 20 and source electrode 16, depletion layer 31 on the inner side of field stop region 1a and depletion layer 32 on the outer side of field stop region la are combined together, and the combined depletion layer protrudes toward peripheral edge 10c. It is thus believed that a high voltage is applied to peripheral edge 10c.

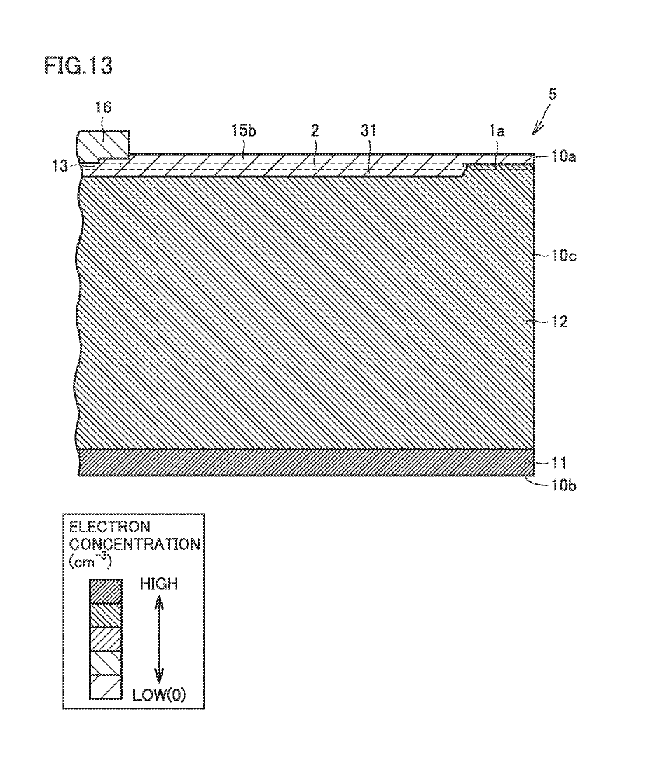

FIG. 12 is a schematic vertical sectional view showing the structure of a MOSFET according to an example. The difference between MOSFET 5 according to the example and MOSFET 5 according to the comparative example is that field stop region 1a is arranged to be exposed at peripheral edge 10c of a chip in MOSFET 5 according to the example.

FIG. 13 is a diagram showing distribution of electron concentration in MOSFET 5 of the example, when a voltage of 5 V is applied between drain electrode 20 and source electrode 16, and the voltage of each of source electrode 16 and the gate electrode is set to 0 V. Negative fixed charges of Q_{eff}=1×10¹² cm⁻² were introduced into the interface between silicon carbide substrate 10 and insulating film 15b. As shown in FIG. 13, depletion layer 31 protrudes from JTE region 2 into drift region 12. However, since field stop region 1a having a high impurity concentration is arranged to be exposed at peripheral edge 10c, the depletion layer hardly extends in the vicinity of peripheral edge 10c.

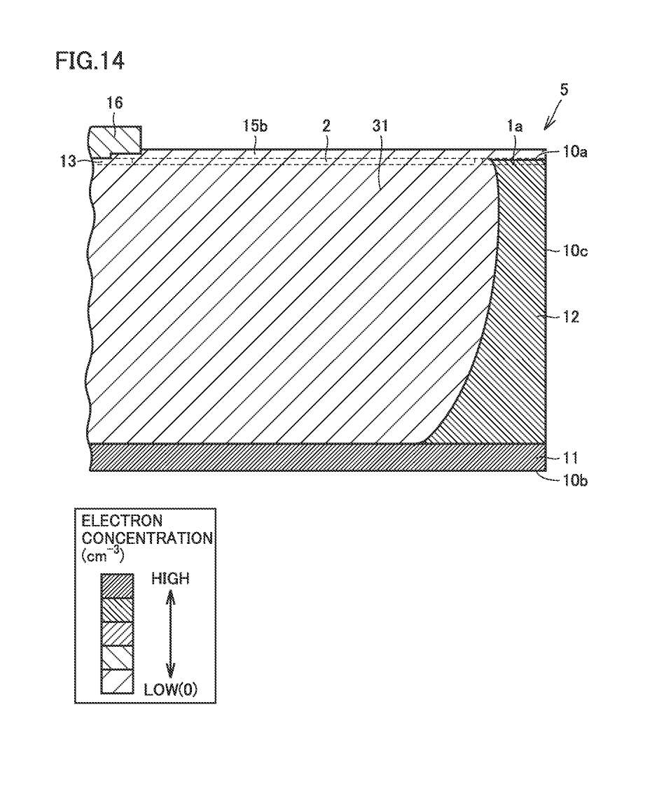

FIG. 14 is a diagram showing distribution of electron concentration in MOSFET 5 of the example, when a voltage of 6500 V is applied between drain electrode 20 and source electrode 16, and the voltage of each of source electrode 16 and the gate electrode is set to 0 V. As shown in FIG. 14, even when a high voltage is applied between drain electrode 20 and source electrode 16, depletion layer 31 hardly extends toward peripheral edge 10c. It is thus believed that a high voltage is not applied to peripheral edge 10c.

Based on the results of the simulations of electron concentration described above, the inventor found that the extension of the depletion layer toward the peripheral edge of the chip could be suppressed by arranging the field stop region to be exposed at the peripheral edge of the chip. As a result, the application of a high voltage to the peripheral edge of the chip can be suppressed, so that the breakdown voltage of the silicon carbide semiconductor device can be improved.

Next, the embodiment of the present invention will be listed and described.

(1) A silicon carbide semiconductor device 5 according to one embodiment of the present invention has a silicon carbide substrate 10 and an insulating film 15b. Silicon carbide substrate 10 includes a termination region OR having a peripheral edge 10c, and an element region IR surrounded by termination region OR. Insulating film 15b is provided on termination region OR. Termination region OR includes a first impurity region 12 having a first conductivity type, and a field stop region 1a having the first conductivity type, being in contact with first impurity region 12 and having a higher impurity concentration than first impurity region 12. Field stop region 1a is at least partially exposed at peripheral edge 10c. The extension of a depletion layer toward peripheral edge 10c of silicon carbide semiconductor device 5 can thereby be suppressed. As a result, the application of a high voltage to peripheral edge 10c of silicon carbide semiconductor device 5 can be suppressed, so that the breakdown voltage of silicon carbide semiconductor device 5 can be improved.

(2) In silicon carbide semiconductor device 5 according to (1) described above, the impurity concentration in field stop region 1a may be not less than 1×10¹⁶ cm⁻³ and not more than 1×10²¹ cm⁻³. By setting the impurity concentration to be not less than 1×10¹⁶ cm⁻³, the extension of a depletion layer can be suppressed. By setting the impurity concentration to be not more than 1×10²¹ cm⁻³, the generation of a leak current due to degraded crystallinity can be suppressed.

(3) In silicon carbide semiconductor device 5 according to (1) or (2) described above, termination region OR may include a guard ring region 3 surrounded by field stop region 1a and having a second conductivity type different from the first conductivity type. The breakdown voltage of silicon carbide semiconductor device 5 can thereby be further improved.

(4) In silicon carbide semiconductor device 5 according to any one of (1) to (3) described above, insulating film 15b may be a thermal oxide film. In the case in which insulating film 15b is a thermal oxide film, a fixed charge density is higher and a depletion layer is more likely to extend than in the case in which insulating film 15b is a deposited oxide film. Thus, silicon carbide semiconductor device 5 according to (1) described above is utilized more suitably for the case in which insulating film 15b is a thermal oxide film.

(5) In silicon carbide semiconductor device 5 according to any one of (1) to (4) described above, the first conductivity type may be n type. The on-resistance of silicon carbide semiconductor device 5 can thereby be reduced.

(6) In silicon carbide semiconductor device 5 according to any one of (1) to (5) described above, silicon carbide substrate 10 may have a first main surface 10a in contact with insulating film 15b, and a second main surface 10b opposite to the first main surface. Silicon carbide semiconductor device 5 may further include a first electrode 16 in contact with first main surface 10a, and a second electrode 20 in contact with second main surface 10b. In the case of a vertical type semiconductor device, a high voltage is applied between first main surface 10a and second main surface 10b, and therefore, a high voltage is likely to be applied to peripheral edge 10c located between first main surface 10a and second main surface 10b. Accordingly, silicon carbide semiconductor device 5 according to (1) described above is utilized more suitably for a vertical type semiconductor.

(7) In silicon carbide semiconductor device 5 according to any one of (1) to (6) described above, element region IR may include a source region 14 having the first conductivity type. An impurity concentration in source region 14 may be identical to the impurity concentration in field stop region 1a. That the impurity concentration in source region 14 is identical to the impurity concentration in field stop region 1a means that a maximum value of the impurity concentration in source region 14 is within ±10% of a maximum value of the impurity concentration in field stop region 1a. The impurity concentration in each region can be measured by SIMS (Secondary Ion Mass Spectroscopy), for example. By simultaneously forming source region 14 and field stop region 1a, the process of manufacturing silicon carbide semiconductor device 5 can be simplified.

(8) In silicon carbide semiconductor device 5 according to any one of (1) to (6) described above, element region IR may include a source region 14 having the first conductivity type. Source region 14 may be formed simultaneously with field stop region 1a. The process of manufacturing silicon carbide semiconductor device 5 can thereby be simplified.

### Details of Embodiment of the Present Invention

The embodiment of the present invention will be described below based on the drawings. It is noted that the same or corresponding parts are designated by the same reference numbers in the following drawings, and description thereof will not be repeated. Regarding crystallographic indications in the present specification, an individual orientation is represented by [ ], a group orientation is represented by < >, an individual plane is represented by ( ) and a group plane is represented by { }. In addition, a negative crystallographic index is normally expressed by putting “−” (bar) above a numeral, but is expressed by putting a negative sign before the numeral in the present specification.

The configuration of a MOSFET as a silicon carbide semiconductor device according to the embodiment of the present invention will be described.

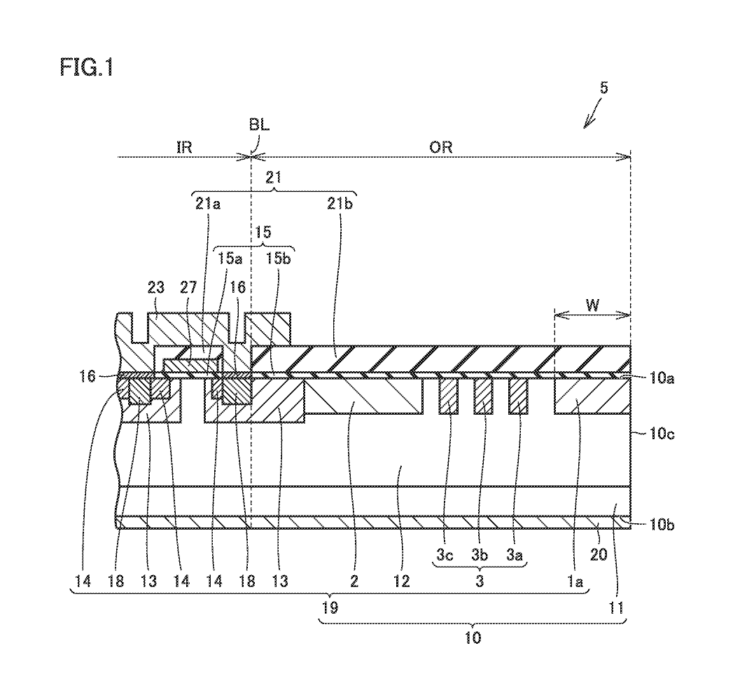

As shown in FIG. 1, a MOSFET 5 according to the embodiment mainly has a silicon carbide substrate 10, a gate electrode 27, a first insulating film 15, a second insulating film 21, a source electrode 16, a source line 23, and a drain electrode 20, for example. Silicon carbide substrate 10 has a first main surface 10a, and a second main surface 10b opposite to first main surface 10a. Silicon carbide substrate 10 is formed of a silicon carbide single-crystal substrate 11, and a silicon carbide epitaxial layer 19 provided on silicon carbide single-crystal substrate 11. Silicon carbide single-crystal substrate 11 is a hexagonal silicon carbide having a polytype of 4H, for example. First main surface 10a has a maximum diameter greater than 100 mm, for example, and preferably equal to or greater than 150 mm. First main surface 10a is a plane angled off by not more than 4° relative to a {0001} plane, for example. Specifically, first main surface 10a is a plane angled off by not more than about 4° relative to a (0001) plane, for example.

Silicon carbide epitaxial layer 19 mainly has a drift region 12, a body region 13, a source region 14, a contact region 18, a JTE region 2, a guard ring region 3, and a field stop region 1a. Drift region 12 is an n type (first conductivity type) region including an n type impurity such as nitrogen or phosphorus. The concentration of the n type impurity in drift region 12 is not less than 1.0×10¹⁴ cm⁻³ and not more than 1.0×10¹⁷ cm⁻³, for example. Body region 13 is a p type (second conductivity type) region including a p type impurity such as aluminum or boron. The concentration of the p type impurity included in body region 13 is about 1×10¹⁷ cm⁻³, for example.

Source region 14 is an n type region including an n type impurity such as nitrogen or phosphorus. Source region 14 is provided to be surrounded by body region 13 in a field of view seen from a direction perpendicular to first main surface 10a (in plan view). The concentration of the n type impurity included in source region 14 is higher than the concentration of the n type impurity included in drift region 12. The concentration of the n type impurity included in source region 14 is 1×10²⁰ cm⁻³, for example. Source region 14 is separated from drift region 12 by body region 13.

Contact region 18 is a p type region including a p type impurity such as aluminum or boron. Contact region 18 is provided to be surrounded by source region 14 in plan view. Contact region 18 is in contact with body region 13. The concentration of the p type impurity included in contact region 18 is higher than the concentration of the p type impurity included in body region 13. The concentration of the p type impurity included in contact region 18 is 1×10²⁰ cm⁻³, for example.

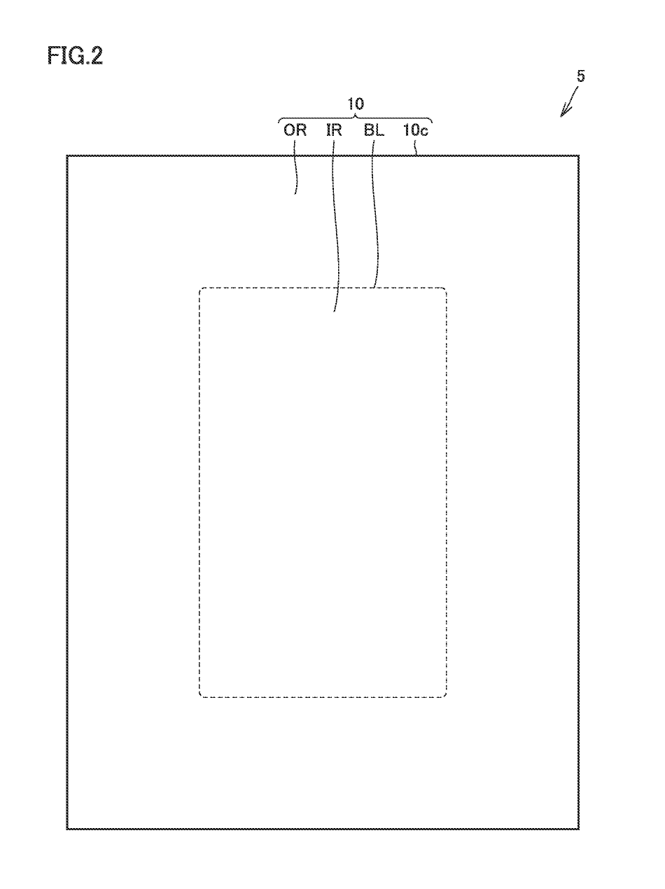

FIG. 2 is a schematic plan view showing silicon carbide substrate 10 included in silicon carbide semiconductor device 5. Silicon carbide substrate 10 is formed of a termination region OR including a peripheral edge 10c, and an element region IR surrounded by termination region OR. Peripheral edge 10c is an outer peripheral surface of silicon carbide semiconductor device 5 (semiconductor chip). In plan view, silicon carbide substrate 10 may have a quadrangular shape, for example, and more specifically, may have a rectangular shape. In plan view, the shape of peripheral edge 10c may be similar to the shape of a boundary BL between termination region OR and element region IR. Element region IR includes body region 13, source region 14, contact region 18, and part of drift region 12 (see FIG. 1). Termination region OR includes field stop region 1a, JTE region 2, guard ring region 3, part of drift region 12, and part of body region 13 (see FIG. 1). Drift region 12 and body region 13 may be included in element region IR and termination region OR.

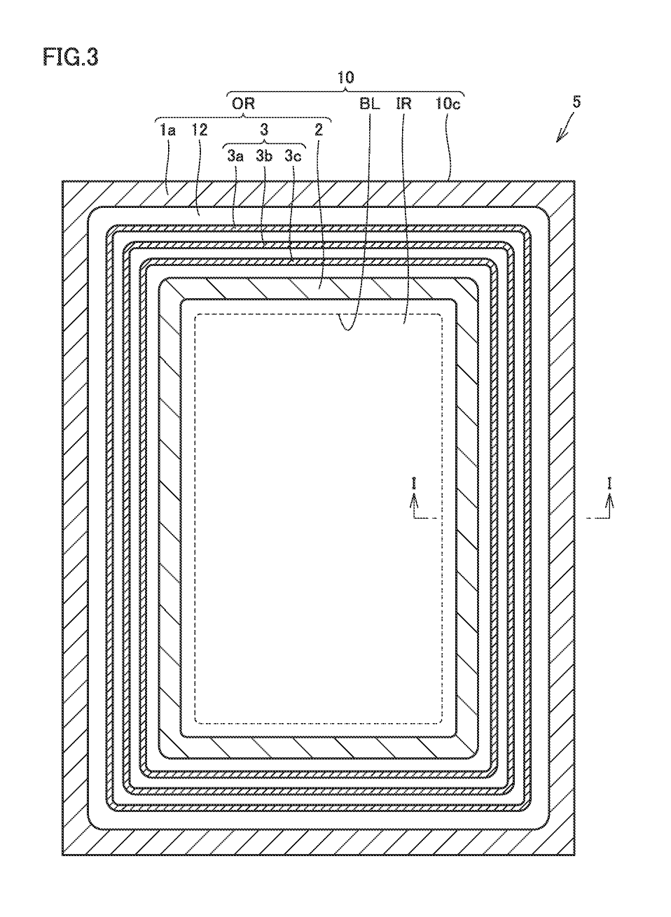

As shown in FIG. 3, termination region OR includes drift region 12 having n type conductivity, and field stop region 1a having n type conductivity, being in contact with drift region 12 and having a higher impurity concentration than drift region 12. Field stop region 1a is at least partially exposed at peripheral edge 10c. Put another way, peripheral edge 10c of silicon carbide substrate 10 is at least partially formed of field stop region 1a. Preferably, the entire periphery of field stop region 1a is exposed at peripheral edge 10c. Put another way, the entire peripheral edge 10c of silicon carbide substrate 10 is formed of field stop region 1a.

Field stop region 1a is a region having n type conductivity (first conductivity type) and including an n type impurity such as nitrogen or phosphorus. Field stop region 1a is in contact with drift region 12 and has a higher impurity concentration than drift region 12. The concentration of the n type impurity in field stop region 1a is not less than 1×10¹⁶ cm⁻³ and not more than 1×10²¹ cm⁻³, for example, and preferably not less than 1×10¹⁷ cm⁻³ and not more than 1×10²⁰ cm⁻³. The concentration of the n type impurity in source region 14 may be identical to the concentration the n type impurity in field stop region 1a. That the impurity concentration in source region 14 is identical to the impurity concentration in field stop region 1a means that a maximum value of the impurity concentration in source region 14 is within ±10% of a maximum value of the impurity concentration in field stop region 1a.

Source region 14 may be formed simultaneously with field stop region 1a. In the case in which source region 14 and field stop region 1a are simultaneously formed, a concentration profile of the n type impurity in source region 14 is substantially the same as a concentration profile of the n type impurity in field stop region 1a in the direction perpendicular to first main surface 10a. For example, in the direction perpendicular to first main surface 10a, the position of a peak of the concentration of the n type impurity in source region 14 is substantially the same as the position of a peak of the concentration of the n type impurity in field stop region 1a. In a direction parallel to first main surface 10a, a width W of field stop region 1a (see FIG. 1) is not less than 25 μm and not more than 300 μm, for example.

As shown in FIG. 3, termination region OR may include guard ring region 3 surrounded by field stop region 1a and having p type conductivity different from the n type conductivity. Guard ring region 3 is a p type region including a p type impurity such as aluminum or boron. A dose amount in guard ring region 3 is not less than 5×10¹² cm⁻² and not more than 2.5×10¹³ cm⁻², for example. Guard ring region 3 may be spaced from field stop region 1a. Guard ring region 3 may have a plurality of (three, for example) guard rings 3a, 3b and 3c.

As shown in FIG. 3, termination region OR may include JTE region 2 surrounded by guard ring region 3. Put another way, guard ring region 3 is located between JTE region 2 and field stop region 1a. JTE region 2 is a p type region including a p type impurity such as aluminum or boron. A dose amount in JTE region 2 is not less than 5×10¹² cm⁻² and not more than 2.5×10¹³ cm⁻², for example. As shown in FIG. 1, JTE region 2 may be in contact with body region 13. The boundary between JTE region 2 and body region 13 corresponds to boundary BL between element region IR and termination region OR. In the direction perpendicular to first main surface 10a, the thickness of JTE region 2 may be smaller than the thickness of body region 13. In the direction perpendicular to first main surface 10a, the thickness of guard ring region 3 may be substantially the same as the thickness of JTE region 2.

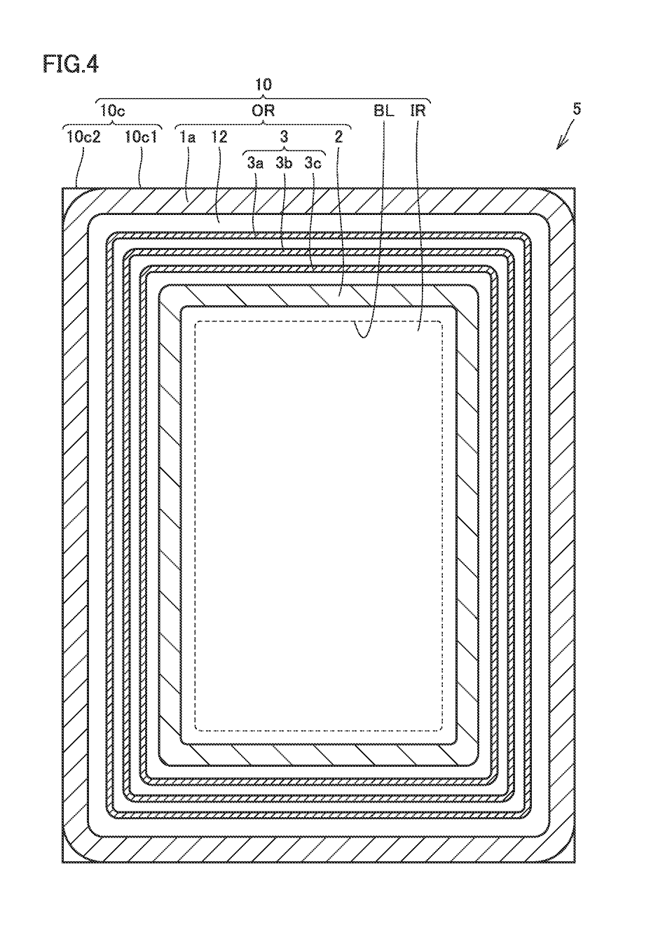

As shown in FIG. 4, field stop region 1a may be exposed at only a portion of peripheral edge 10c. Put another way, peripheral edge 10c may have a first region 10c1 formed of field stop region 1a, and a second region 10c2 formed of a region other than field stop region 1a (drift region 12, for example). As shown in FIG. 4, the corner portions of termination region OR may be formed of drift region 12.

As shown in FIG. 1, first insulating film 15 is provided on first main surface 10a of silicon carbide substrate 10. First main surface 10a is in contact with first insulating film 15. The thickness of first insulating film 15 is not less than 40 nm and not more than 60 nm, for example. First insulating film 15 may be a thermal oxide film or a deposited oxide film. First insulating film 15 may be silicon dioxide, silicon nitride, or polyimide. It is believed that an interface state is more likely to be formed at the interface between silicon carbide substrate 10 and first insulating film 15 in the case in which first insulating film 15 is a thermal oxide film, than in the case in which first insulating film 15 is a deposited oxide film. First insulating film 15 has a gate insulating film 15a and a third insulating film 15b. Gate insulating film 15a may be in contact with or spaced from third insulating film 15b. Gate insulating film 15a is provided on element region IR. Gate insulating film 15a is in contact with source region 14, body region 13 and drift region 12 at first main surface 10a.

Third insulating film 15b is provided in contact with termination region OR. Third insulating film 15b may be in contact with source electrode 16 at boundary BL between element region IR and termination region OR. Third insulating film 15b is in contact with JTE region 2, guard ring region 3, field stop region 1a, drift region 12 and body region 13 at first main surface 10a. Third insulating film 15b may be provided on a contact between first main surface 10a and peripheral edge 10c.

Gate electrode 27 is provided on gate insulating film 15a. Gate electrode 27 is provided to face source region 14, body region 13 and drift region 12. Gate electrode 27 is made of a conductor such as polysilicon doped with an impurity, for example.

Second insulating film 21 has an interlayer insulating film 21a and a fourth insulating film 21b. Second insulating film 21 includes silicon dioxide, for example. Interlayer insulating film 21a may be in contact with or spaced from fourth insulating film 21b. Interlayer insulating film 21a is provided on element region IR. Interlayer insulating film 21a is provided in contact with each of gate electrode 27 and gate insulating film 15a so as to cover gate electrode 27. Interlayer insulating film 21a electrically insulates gate electrode 27 and source electrode 16 from each other. Fourth insulating film 21b is provided on third insulating film 15b. Fourth insulating film 21b is provided on boundary BL between element region IR and termination region OR.

Source electrode 16 is in contact with first main surface 10a. Source electrode 16 is in contact with source region 14 and contact region 18 at first main surface 10a. Source electrode 16 is provided on element region IR. Source electrode 16 includes TiAlSi, for example. Preferably, source electrode 16 is in ohmic contact with each of source region 14 and contact region 18. Source line 23 is in contact with source electrode 16, and is provided to cover interlayer insulating film 21a. Source line 23 is electrically connected to source region 14 with source electrode 16 interposed therebetween. Source line 23 is made of a material including aluminum, for example.

Drain electrode 20 is in contact with second main surface 10b. Drain electrode 20 is in contact with silicon carbide single-crystal substrate 11 at second main surface 10b. Drain electrode 20 is made of a material including NiSi, for example. Preferably, drain electrode 20 is in ohmic contact with silicon carbide single-crystal substrate 11 having n type conductivity. Drain electrode 20 is in contact with element region IR and termination region OR.

Next, a method of manufacturing the MOSFET as the silicon carbide semiconductor device according to the embodiment of the present invention will be described.

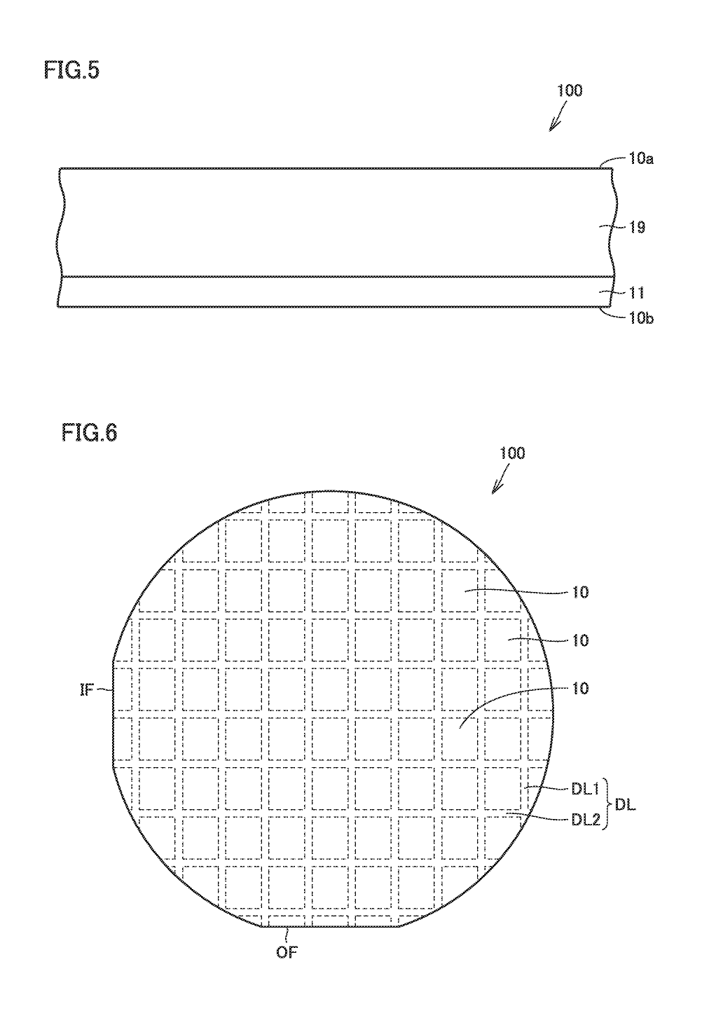

First, a silicon carbide substrate is prepared. A silicon carbide single crystal formed by sublimation is sliced, for example, to prepare silicon carbide single-crystal substrate 11. Silicon carbide single-crystal substrate 11 is a hexagonal silicon carbide having a polytype of 4H, for example. Then, silicon carbide epitaxial layer 19 is formed on one main surface of silicon carbide single-crystal substrate 11 by CVD (Chemical Vapor Deposition), for example. Epitaxial growth is performed using a mixed gas of SiH₄ (silane) and C₃H₈ (propane) as a material gas, for example. During the epitaxial growth, an n type impurity such as nitrogen is introduced into silicon carbide epitaxial layer 19. In this way, a silicon carbide wafer 100 having silicon carbide epitaxial layer 19 provided on silicon carbide single-crystal substrate 11 is prepared. Silicon carbide wafer 100 has first main surface 10a formed of silicon carbide epitaxial layer 19, and second main surface 10b formed of silicon carbide single-crystal substrate 11 (see FIG. 5).

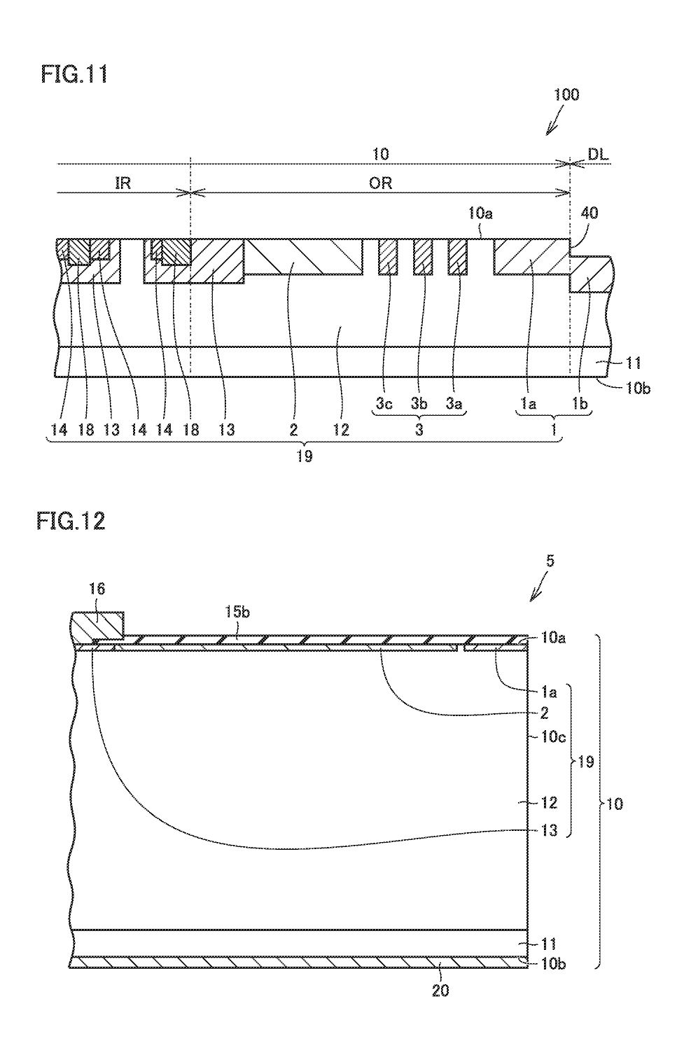

As shown in FIG. 6, silicon carbide wafer 100 may be provided with an orientation flat OF and an index flat IF. Orientation flat OF may extend along a <11-20> direction, for example. Index flat IF may extend along a <1-100> direction, for example. A dicing-planned region DL may be provided on the first main surface 10a side of silicon carbide wafer 100. Dicing-planned region DL may have first dicing lines DL1 extending in the <1-100> direction and second dicing lines DL2 extending along the <11-20> direction, for example. Silicon carbide wafer 100 includes a plurality of silicon carbide substrates 10 separated by dicing-planned region DL. Each of the plurality of silicon carbide substrates 10 is surrounded by first dicing lines DL1 and second dicing lines DL2. Dicing-planned region DL is a region which will be cut in a dicing step described later. As shown in FIG. 11, dicing-planned region DL may or may not be provided with a trench 40.

Next, an ion implantation step is performed. Specifically, an implantation mask (not shown) having a desired opening pattern is formed on first main surface 10a of silicon carbide wafer 100. Then, ions of a p type impurity such as aluminum or boron are implanted into first main surface 10a of silicon carbide wafer 100, to form body region 13 having p type conductivity. Then, ions of an n type impurity such as nitrogen or phosphorus are implanted into body region 13, to form source region 14 having n type conductivity. Then, ions of a p type impurity such as aluminum or boron are implanted into source region 14, to form contact region 18 having p type conductivity.

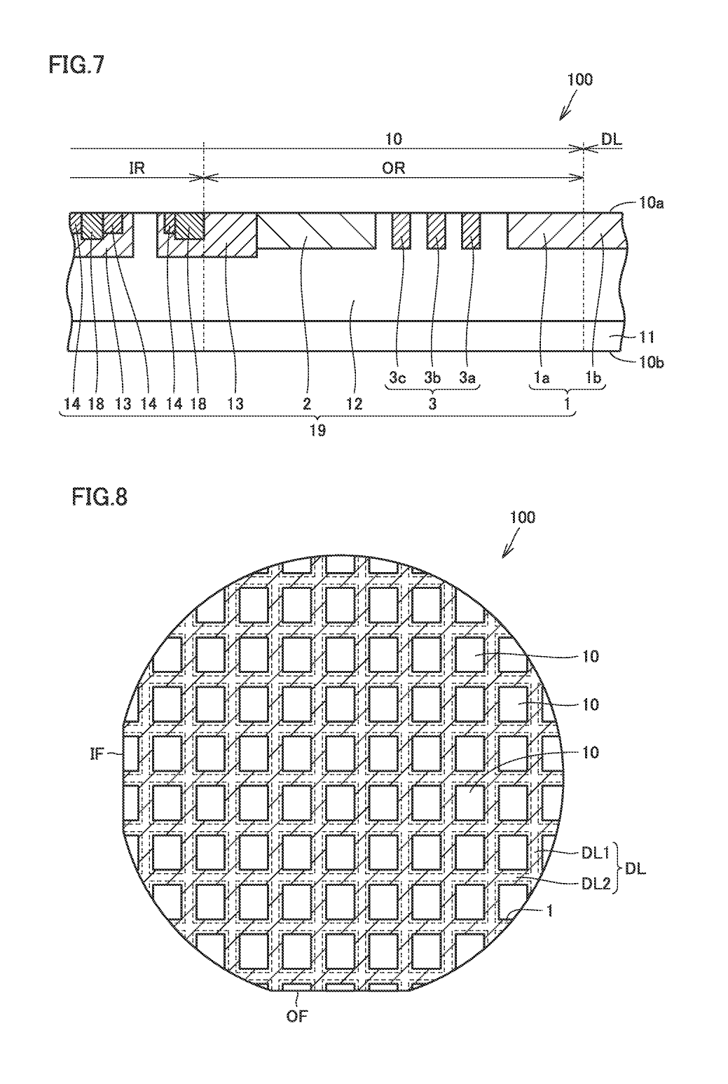

Similarly, ions of a p type impurity such as aluminum or boron are implanted into first main surface 10a of silicon carbide wafer 100, to form JTE region 2 and guard ring region 3 having p type conductivity. Ions of an n type impurity such as nitrogen or phosphorus are implanted into first main surface 10a, to form an n type region 1 having n type conductivity. As shown in FIGS. 7 and 8, n type region 1 is formed to cover dicing-planned region DL. Put another way, n type region 1 is formed by implanting ions of an n type impurity such as nitrogen or phosphorus into termination region OR and dicing-planned region DL. The concentration of the n type impurity included in n type region 1 is higher than the concentration of the n type impurity included in drift region 12. N type region 1 includes field stop region 1a formed in termination region OR, and a first n type region lb formed in dicing-planned region DL. Source region 14 may be formed simultaneously with field stop region 1a. Field stop region 1a may be formed simultaneously with first n type region lb. N type region 1 may be arranged in a grid pattern in plan view (see FIG. 8).

Next, heat treatment is performed for activating the impurities introduced into silicon carbide wafer 100 by the ion implantations described above. Specifically, silicon carbide wafer 100 into which the ions have been implanted is heated to about 1700° C. in an argon atmosphere, for example, and held for about 30 minutes.

Next, a step of forming a first insulating film is performed. Specifically, first main surface 10a of silicon carbide wafer 100 is thermally oxidized at about 1300° C., for example, in an oxygen atmosphere, to form first insulating film 15 on first main surface 10a. First insulating film 15 includes gate insulating film 15a and third insulating film 15b. Gate insulating film 15a is in contact with drift region 12, body region 13 and source region 14 at first main surface 10a. Third insulating film 15b is in contact with JTE region 2, drift region 12, guard ring region 3 and field stop region 1a at first main surface 10a.

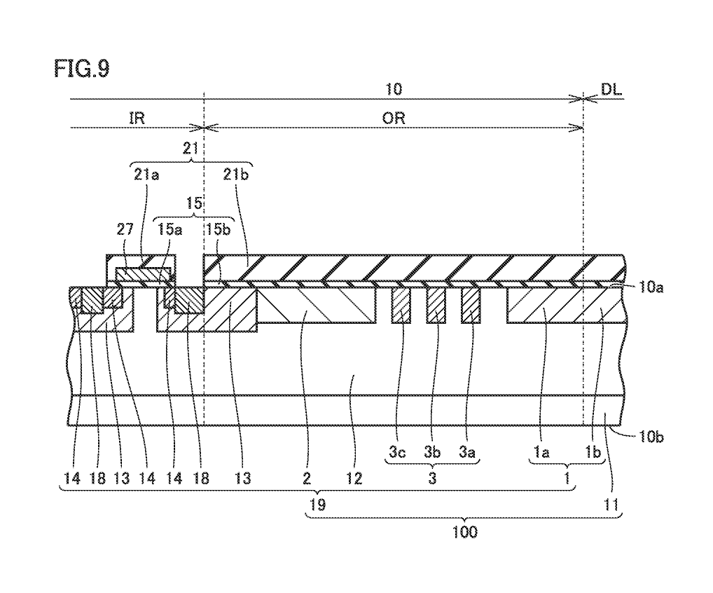

Next, a step of forming a gate electrode is performed. Gate electrode 27 made of a material including polysilicon doped with an impurity, for example, is formed in contact with gate insulating film 15a. Then, a step of forming a second insulating film is performed. Second insulating film 21 made of a material including silicon dioxide, for example, is formed on gate electrode 27 and third insulating film 15b. Second insulating film 21 includes interlayer insulating film 21a provided to cover gate electrode 27, and fourth insulating film 21b provided on third insulating film 15b. Then, first insulating film 15 and second insulating film 21 are partially removed so as to expose contact region 18 and source region 14 at first insulating film 15 (see FIG. 9).

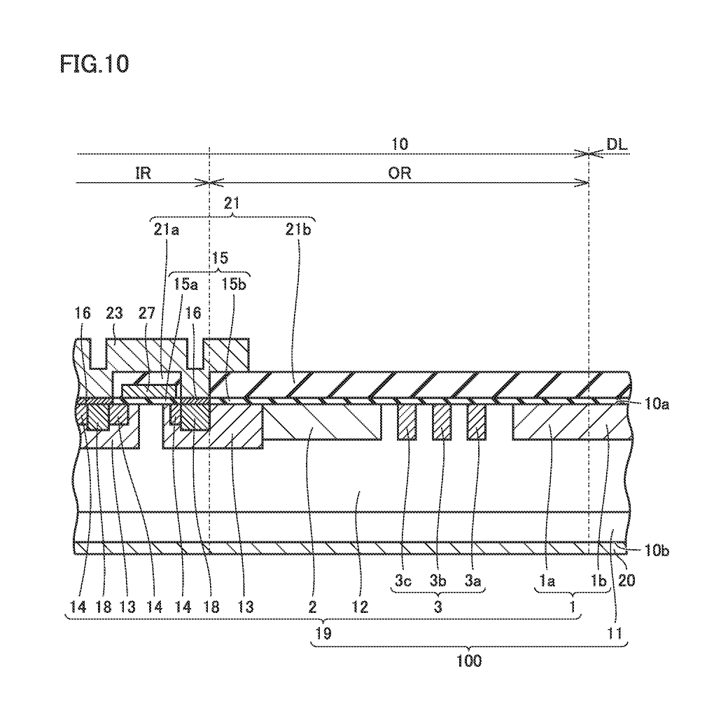

Next, a step of forming a source electrode is performed. For example, source electrode 16 in contact with contact region 18 and source region 14 is formed by sputtering. Source electrode 16 contains Si atoms, Ti atoms and Al atoms, for example. Then, source electrode 16 and silicon carbide wafer 100 are heated to about 1000° C., for example, to form source electrode 16 in ohmic contact with silicon carbide wafer 100. Then, source line 23 in contact with source electrode 16 is formed. Source line 23 is made of a material including aluminum, for example. Then, drain electrode 20 in contact with second main surface 10b of silicon carbide wafer 100 is formed (see FIG. 10).

Next, a dicing step is performed. Silicon carbide wafer 100 is cut along dicing-planned region DL (see FIGS. 6 and 10) by a rotating blade (not shown), for example. In the dicing step, dicing-planned region DL including first n type region 1b is removed while field stop region 1a remains in silicon carbide substrate 10. A plurality of chips are thereby formed. Each of the plurality of chips forms silicon carbide semiconductor device 5 (FIG. 1).

Next, a variation of the structure of the dicing-planned region will be described.

As shown in FIG. 11, in dicing-planned region DL, trench 40 may be formed in first main surface 10a. The depth of trench 40 may be smaller than the thickness of field stop region 1a. In the case in which trench 40 is formed in dicing-planned region DL, n type region 1 may be formed to be exposed at the bottom and the sides of the trench at the ion implantation step.

Although the first conductivity type has been described as n type and the second conductivity type as p type in the above embodiment, the first conductivity type may be p type and the second conductivity type may be n type. Although the planar type MOSFET has been described as an example silicon carbide semiconductor device, the silicon carbide semiconductor device may be a trench type MOSFET. The silicon carbide semiconductor device may be a lateral type semiconductor device or a vertical type semiconductor device. The silicon carbide semiconductor device may be a Schottky barrier diode, a PiN diode, an IGBT (Insulated Gate Bipolar Transistor), a JFET (Junction Field Effect Transistor), a thyristor, a GTO (Gate Turn off thyristor), or the like.

Next, the function and effect of the silicon carbide semiconductor device according to the embodiment of the present invention will be described.

MOSFET 5 according to the embodiment has silicon carbide substrate 10 and third insulating film 15b. Silicon carbide substrate 10 includes termination region OR having peripheral edge 10c, and element region IR surrounded by termination region OR. Third insulating film 15b is provided on termination region OR. Termination region OR includes drift region 12 having n type conductivity, and field stop region 1a having n type conductivity, being in contact with drift region 12 and having a higher n type impurity concentration than drift region 12. Field stop region 1a is at least partially exposed at peripheral edge 10c. The extension of a depletion layer toward peripheral edge 10c of MOSFET 5 can thereby be suppressed. As a result, the application of a high voltage to peripheral edge 10c of MOSFET 5 can be suppressed, so that the breakdown voltage of MOSFET 5 can be improved.

Furthermore, in MOSFET 5 according to the embodiment, the impurity concentration in field stop region 1a is not less than 1×10¹⁶ cm⁻³ and not more than 1×10²¹ cm⁻³. By setting the impurity concentration to be not less than 1×10¹⁶ cm⁻³, the extension of a depletion layer can be suppressed. By setting the impurity concentration to be not more than 1×10²¹ cm⁻³, the generation of a leak current due to degraded crystallinity can be suppressed.

Furthermore, in MOSFET 5 according to the embodiment, termination region OR includes guard ring region 3 surrounded by field stop region 1a and having p type conductivity different from the n type conductivity. The breakdown voltage of MOSFET 5 can thereby be further improved.

Furthermore, in MOSFET 5 according to the embodiment, third insulating film 15b is a thermal oxide film. In the case in which third insulating film 15b is a thermal oxide film, a fixed charge density is higher and a depletion layer is more likely to extend than in the case in which third insulating film 15b is a deposited oxide film. Thus, MOSFET 5 according to above is utilized more suitably for the case in which third insulating film 15b is a thermal oxide film.

Furthermore, in MOSFET 5 according to the embodiment, the first conductivity type is n type. The on-resistance of MOSFET 5 can thereby be reduced.

Furthermore, in MOSFET 5 according to the embodiment, silicon carbide substrate 10 has first main surface 10a in contact with third insulating film 15b, and second main surface 10b opposite to the first main surface. MOSFET 5 may further include source electrode 16 in contact with first main surface 10a, and drain electrode 20 in contact with second main surface 10b. In the case of a vertical type semiconductor device, a high voltage is applied between first main surface 10a and second main surface 10b , and therefore, a high voltage is likely to be applied to peripheral edge 10c located between first main surface 10a and second main surface 10b. Accordingly, MOSFET 5 according to above is utilized more suitably for a vertical type semiconductor.

Furthermore, in MOSFET 5 according to the embodiment, element region IR may include source region 14 having the first conductivity type. An impurity concentration in source region 14 may be identical to the impurity concentration in field stop region 1a. By simultaneously forming source region 14 and field stop region 1a, the process of manufacturing MOSFET 5 can be simplified.

Furthermore, in MOSFET 5 according to the embodiment, element region IR may include source region 14 having the first conductivity type. Source region 14 may be formed simultaneously with field stop region 1a. The process of manufacturing MOSFET 5 can thereby be simplified.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 n type region; 1a field stop region; lb first n type region; 2 JTE region; 3 guard ring region; 3a guard ring; 5 silicon carbide semiconductor device (MOSFET); 10 silicon carbide substrate; 10a first main surface; 10b second main surface; 10c1 first region; 10c2 second region; 10c peripheral edge; 11 silicon carbide single-crystal substrate; 12 first impurity region (drift region); 13 body region; 14 source region; 15 first insulating film; 15a gate insulating film; 15b third insulating film (insulating film); 16 source electrode (first electrode); 18 contact region; 19 silicon carbide epitaxial layer; 20 drain electrode (second electrode); 21 second insulating film; 21a interlayer insulating film; 21b fourth insulating film; 23 source line; 27 gate electrode; 31, 32 depletion layer; 40 trench; 100 silicon carbide substrate wafer; BL boundary; DL dicing-planned region; DL1 first dicing line; DL2 second dicing line; IF index flat; IR element region; OF orientation flat; OR termination region.

1. A silicon carbide semiconductor device comprising:
a silicon carbide substrate including a termination region having a peripheral edge, and an element region surrounded by the termination region; and
an insulating film provided on the termination region,
the termination region including
a first impurity region having a first conductivity type, and
a field stop region having the first conductivity type, being in contact with the first impurity region and having a higher impurity concentration than the first impurity region,
the field stop region being at least partially exposed at the peripheral edge.

2. The silicon carbide semiconductor device according to claim 1, wherein
the impurity concentration in the field stop region is not less than 1×10¹⁶ cm⁻³ and not more than 1×10²¹ cm⁻³.

3. The silicon carbide semiconductor device according to claim 1, wherein
the termination region includes a guard ring region surrounded by the field stop region and having a second conductivity type different from the first conductivity type.

4. The silicon carbide semiconductor device according to claim 1, wherein
the insulating film is a thermal oxide film.

5. The silicon carbide semiconductor device according to claim 1, wherein
the first conductivity type is n type.

6. The silicon carbide semiconductor device according to claim 1, wherein
the silicon carbide substrate has a first main surface in contact with the insulating film, and a second main surface opposite to the first main surface, and
the silicon carbide semiconductor device further comprises a first electrode in contact with the first main surface, and a second electrode in contact with the second main surface.

7. The silicon carbide semiconductor device according to claim 1, wherein
the element region includes a source region having the first conductivity type, and
an impurity concentration in the source region is identical to the impurity concentration in the field stop region.

8. The silicon carbide semiconductor device according to claim 1, wherein
the element region includes a source region having the first conductivity type, and
the source region is formed simultaneously with the field stop region.
